(19) United States
(12) Patent Application Publication
(10) Pub. No.: US 2012/0193227 A1
(43) Pub. Date: Aug. 2, 2012

(54) MAGNET ARRAY FOR A PHYSICAL VAPOR DEPOSITION SYSTEM

(76) Inventors: Brian S. Tryon, Glastonbury, CT (US); Russell A. Beers, Manchester, CT (US)

(21) Appl. No.: 13/019,326

(22) Filed: Feb. 2, 2011

(51) Int. Cl. C23C 14/35; H01F 7/02

(52) U.S. Cl. 204/298.16; 335/306

(57) ABSTRACT

A magnet array for a steered arc physical vapor deposition system has multiple magnets sandwiched between two pole plates.

### BACKGROUND

The present disclosure is related to physical vapor deposition (PVD) systems, and in particular, to a magnetic array for use within a post cathode.

Cathodic arc is one type physical vapor deposition (PVD) system which is utilized to form coatings by vaporizing a material and depositing that material on a piece, thereby coating the piece with a thin layer of the material. Cathodic arc systems use a cathode/anode arrangement where the cathode includes an evaporation surface made from the coating material. The cathode and the anode of the PVD system are contained within a vacuum chamber. A power source is connected to the cathode and the anode with the positive connection of the power source connected to the anode and the negative connection of the power source connected to the cathode. By connecting the positive power connection to the anode and the negative power connection to the cathode, a charge disparity between the anode and the cathode is generated. The charge disparity causes an electrical arc to jump between the cathode and the anode. In standard PVD systems, the arc location is random over the surface of the cathode. The arcing causes the surface of the cathode to vaporize at the point where the arc occurred. The vaporized cathode material then coats the piece contained in the vacuum chamber.

In order to control the density and distribution of the coating, steered arc systems control the location of the arc on the cathode's surface by manipulating magnetic fields within and around the cathode. This also aids in the regular/even wearing of the cathode/source material, thus, helping to allow for the most useful consumption of the cathode/source material during the coating deposition process.

### SUMMARY

Disclosed is a post cathode PVD system having a post cathode and a magnet array movably suspended within the post cathode. The magnet array has a plurality of magnets sandwiched between a first pole plate and a second pole plate.

Also disclosed is a magnet array having, a first pole plate, a second pole plate, a plurality of permanent magnets between the first and second pole plate, and a fastening feature for connecting the pole plates to a shaft.

### BRIEF DESCRIPTION OF THE DRAWINGS

The disclosure can be further understood by reference to the following detailed description when considered in connection with the accompanying drawings wherein:

FIG. 1 schematically illustrates an example PVD system having a post cathode.

FIG. 2 illustrates an example post cathode for use in the PVD system of FIG. 1.

FIG. 3 illustrates an example magnet array for use in the post cathode of FIG. 2.

FIG. 4 illustrates a top view of the example array of FIG. 3.

### DETAILED DESCRIPTION

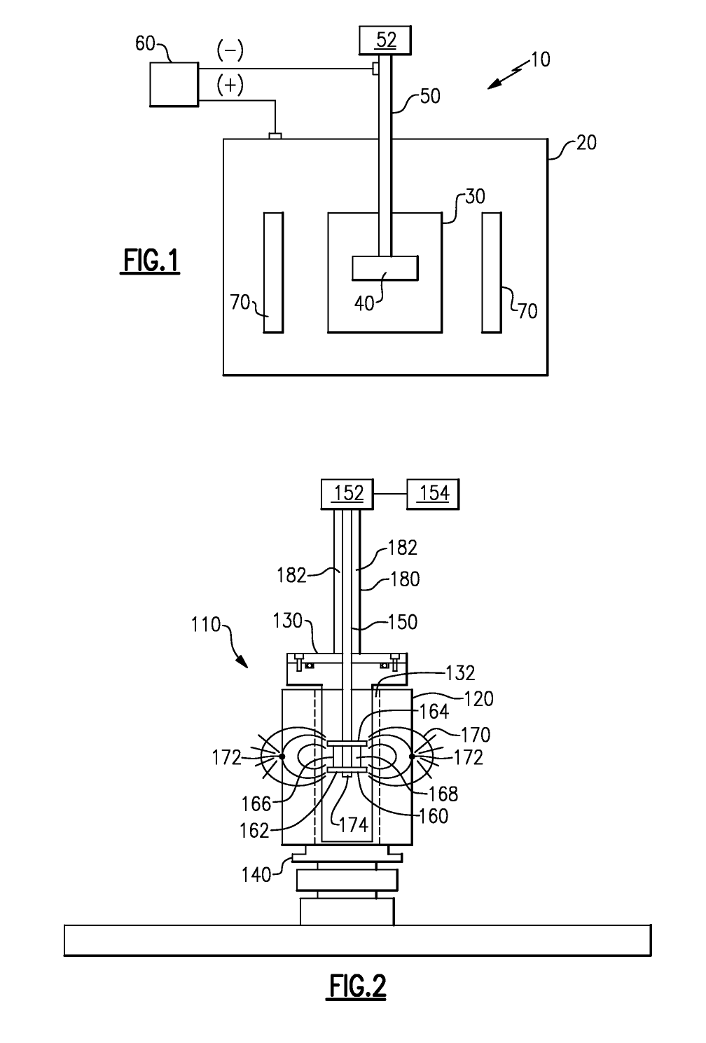

FIG. 1 illustrates an example physical vapor deposition (PVD) system 10 using a post cathode 30. The post cathode 30 is located within a vacuum chamber 20. One or more parts 70 are placed within the vacuum chamber 30 adjacent to the post cathode 30. An inner surface of the vacuum chamber 20 doubles as an anode for the PVD system 10. Alternately, an independent anode may be used within the vacuum chamber 20. A magnetic array 40 is suspended within a hollow center of the post cathode 30 via a shaft 50. The shaft 50 can be actuated with a linear actuator 52, thereby moving the magnet array 40 linearly along an axis defined by the shaft 50. Alternate methods of axially moving the magnet 40 can be used, with minor modifications to the disclosed system.

When power is supplied from a power source 60 to the PVD system 10, the cathode 30 arcs at or near a point on its surface having the strongest intersection with a magnetic field produced by the magnet array 40. Moving the magnet array 40 adjusts the location of the magnetic field, and thus the location of the arc. Control over the location of the cathodic arc provides a degree of control over the coating density distribution by controlling where the coating vapor originates. It is understood in the art that sections of a part 70 closer to a point of vapor origination will receive a denser coating than sections of the part 70 that are farther away from the point of vapor origination.

FIG. 2 illustrates a detailed schematic drawing of the post cathode 30 and the shaft 50 of FIG. 1, with a shaft 150 corresponding to the shaft 50 of FIG. 1. The shaft 150 extends through a top cathode cap 130 into a hollow center 132 of the cylindrical post cathode 110. The shaft 150 is connected to a magnet array 160. The magnet array 160 is a plurality of post magnets 166, 168 sandwiched together by a top pole plate 164 and a bottom pole plate 162. The magnetic field 170 of the magnet array 160 intersects a side wall of the post cathode 110 at an intersection point 172, thereby causing the arc to occur at or near the intersection point 172. The side wall is a cylinder 120 constructed of an evaporation source material, and is electrically connected to the top cathode cap 130 and the bottom cathode cap 140. As known in the art, the evaporation source material is fabricated from nominally the same material as the desired coating composition.

The shaft 150 extends out of the post cathode 110, and is connected to an actuator 152. The actuator moves the shaft 150 along an axis defined by the shaft 150. Movement of the magnet array 160 attached to the shaft 150 causes a corresponding movement of the intersection point 172. The shaft 150 in the illustrated example is encompassed within a cooling shaft 180. The cooling shaft 180 includes fluid passageways 182 that provide a cooling fluid flow to the post cathode 110. Actuation of the shaft 150 and movement of the magnet array 160 can be controlled using a controller 154 according to known principles.

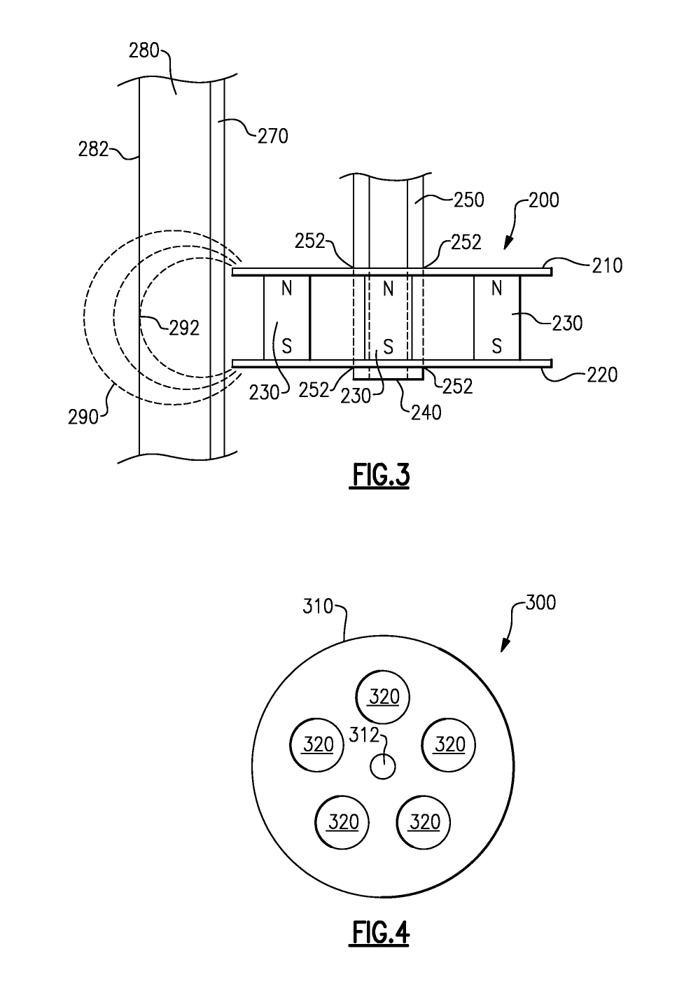

A detailed example magnet array 200 for use in the post cathode 110 of FIG. 2 is illustrated in FIG. 3. The magnet array 200 has multiple individual post magnets 230 sandwiched between a top pole plate 210 and a bottom pole plate 220. The shaft 250 extends through a center hole 252 in each of the pole plates 210, 220, and is attached to the pole plates 210, 220 via an attachment feature 240. Each of the magnets 230 is a standard post magnet, such as a rare-earth magnet, and is attached to the pole plates 210, 220 using known fastening techniques. Alternately, the magnets 230 can be fixed to the pole plates 210, 220 using magnetic forces.

A magnetic field 290 is generated by the magnet array 200, and intersects an exterior surface 282 of a post cathode cylinder 280 at an intersection point 292. The magnetic field 290 is tangential to the exterior surface 282 of the post cathode cylinder 280 at the intersection point 292. The tangential nature of the magnetic field 290/cathode cylinder 280 intersection point 292 causes the strongest effect of the magnetic field to be concentrated at the intersection point 292. This, in turn, forces cathodic arcing to occur at or near the intersection point 292. While FIG. 3 illustrates the post cathode cylinder 280 on only a single side of the magnetic array 200, it is understood that the post cathode cylinder 280 would surround the magnetic array 200.

Each magnet 230 in the magnet array 240 is aligned with each other magnet 230, such that each magnet's north pole contacts a first pole plate 210, and each magnets south pole contacts a second pole plate 220. The pole plates 210, 220 are constructed of a ferro-reactive material, such as iron (Fe), and the magnets 230 are permanent magnets, such as neodymium (Nb—Fe—B) magnets. The ferro-reactivity of the pole plates 210, 220 as well as the North-South alignment of the magnet's 230 poles causes a uniform magnetic field 290 to emanate from the pole plates 210, 220 in the same manner that a magnetic field would emanate from a single solid puck-shaped magnet of the same general dimensions as the magnet array 200. The uniform magnetic field 290 provides a stronger tangential field presence at the intersection 292 with the outside surface 282 of the post cathode 280 than is provided by multiple magnets without a pole plate configuration. Each of the magnets 230 is a standard production magnet.

Turning now to FIG. 4, an example magnet array 300 is illustrated with a top view. The top pole plate is omitted for illustration purposes. As shown in FIG. 4, the pole plate 310 includes a center hole 312 for connecting the array 300 to a shaft. Each of the magnets 320 is arranged about the center hole 312 such that the magnets 320 are equidistant from the center hole 312, and equidistant from two adjacent magnets 320. This configuration can accommodate any number of magnets 320 beyond two, and the number of magnets combined with the strength of each magnet dictates the strength of the generated magnetic field. Each of the magnets can be attached to the pole plate 310 using any known fastening techniques. Alternate configurations creating varied strength or shaped magnetic fields could also be used according to the above disclosure.

The above example magnet array 40 and PVD system 10 are described with regards to a cylindrical post cathode 30 (illustrated in FIG. 1). It is understood, however, that any shape post cathode, such as a rectangular post or a hexagonal post, could be used in place of a cylindrical post with minor modifications to the above disclosure.

Although an example embodiment has been disclosed, a worker of ordinary skill in this art would recognize that certain modifications would come within the scope of the claims. For that reason, the following claims should be studied to determine their true scope and content.

What is claimed is:

1. A post cathode physical vapor deposition (PVD) system comprising:
a post cathode;
a magnet array movably suspended within said post cathode; and
said magnet array further comprising a plurality of magnets sandwiched between a first pole plate and a second pole plate.

2. The post cathode PVD system of claim 1, wherein said magnet array comprises a plurality of permanent magnets having aligned magnetic poles.

3. The post cathode PVD system of claim 2, wherein said first pole plate generates a magnetic north, and said second pole plate generates a magnetic south.

4. The post cathode PVD system of claim 1, wherein each of said magnets in said magnet array is arranged such that said magnet array generates a single uniform magnetic field.

5. The post cathode PVD system of claim 1, wherein said magnet array comprises at least three magnets arranged such that each magnet is equidistant from a center point and each of said magnets is equidistant from two adjacent magnets.

6. The post cathode PVD system of claim 1, wherein a magnetic field generated by said magnet array intersects an exterior surface of said post cathode.

7. The post cathode PVD system of claim 6, wherein at a point of said intersection, said exterior surface of said post cathode is tangential to said magnetic field.

8. The post cathode PVD system of claim 1, wherein each of said plurality of magnets comprises a permanent magnet.

9. The post cathode PVD system of claim 8, wherein each of said plurality of magnets comprises neodymium.

10. The post cathode PVD system of claim 1, wherein said first pole plate and said second pole plate comprise a ferro-reactive material.

11. The post cathode PVD system of claim 10, wherein said ferro-reactive material comprises iron.

12. The post cathode PVD system of claim 5, wherein said magnet array comprises five magnets.

13. A magnet array comprising:
a first pole plate;
a second pole plate;
a plurality of permanent magnets between said first and second pole plate; and
a fastening feature for connecting said pole plates to a shaft.

14. The magnet array of claim 13, wherein said plurality of magnets are arranged such that a single uniform magnetic field is generated, said uniform magnetic field having said first pole plate as a magnetic north and said second pole plate as a magnetic south.

15. The magnet array of claim 13, wherein each of said pole plates comprises a ferro-reactive material.

16. The magnet array of claim 13, wherein each of said pole plates comprises iron.

17. The magnet array of claim 13, wherein each of said magnets comprises a rare earth magnet.

18. The magnet array of claim 17, wherein each of said magnets comprises a neodymium magnet.
